(19) United States
(12) Patent Application Publication
(10) Pub. No.: US 2026/0260852 A1
(43) Pub. Date: Sep. 3, 2026

(54) PROCESS CHAMBER PROCESS KIT WITH PROTECTIVE COATING

(71) Applicant: Applied Materials, Inc., Santa Clara, CA (US)

(72) Inventor: Jian WU, San Jose, CA (US)

(21) Appl. No.: 19/068,660

(22) Filed: Mar. 3, 2025

(51) Int. Cl. H01J 37/32; H01J 9/24; H01J 9/30

(52) U.S. Cl. CPC H01J 37/32495; H01J 9/245; H01J 9/30; H01J 37/32467; H01J 2209/012; H01J 2237/0213

(57) ABSTRACT

A chamber component for a plasma process chamber and methods of fabricating and using the same are provided. In one aspect, a chamber component used within a plasma processing chamber is provided. The chamber component includes a metallic base material that has a surface having an average peak-to-valley distance, Rz_{AVG}, of less than or equal to about 20 micro inches, or about 0.508 microns. The chamber component also includes a silica coating formed over the surface.

### BACKGROUND

### Field

The present disclosure relates generally to tools and components for use in a plasma processing chamber apparatus. More specifically, the present disclosure relates to a method for producing a plasma processing chamber component that is resistive to a corrosive plasma environment.

### Description of the Related Art

Semiconductor processing involves a number of different chemical and physical processes whereby minute integrated circuits are created on a substrate. Layers of materials which make up the integrated circuit are created by chemical vapor deposition, physical vapor deposition, epitaxial growth, and the like. Some of the layers of material are patterned using photoresist masks and wet or dry etching techniques. The substrate utilized to form integrated circuits may be silicon, gallium arsenide, indium phosphide, glass, or other appropriate material.

A typical semiconductor processing chamber includes a chamber body defining a process zone, a gas distribution assembly adapted to supply a gas from a gas supply into the process zone, a gas energizer, e.g., a plasma generator, utilized to energize the process gas to process a substrate positioned on a substrate support assembly, and a gas exhaust. During plasma processing, the energized gas is often comprised of ions and highly reactive species which etches and erodes exposed portions of the processing chamber components, for example, an electrostatic chuck that holds the substrate during processing. Additionally, processing by-products are often deposited on chamber components which are periodically cleaned typically with highly reactive fluorine. In-situ cleaning procedures used to remove the processing byproducts from within the chamber body may further erode the integrity of the processing chamber components. Attack from the reactive species during processing and cleaning reduces the lifespan of the chamber components and increase service frequency. Additionally, flakes from the eroded parts of the chamber components may become a source of particulate contamination during substrate processing. Further, trace metals from the base material of a chamber component may leach out of the chamber component and contaminate the substrate. As such, the chamber components are generally replaced after a number of process cycles and before the chamber components provide inconsistent or undesirable properties during substrate processing. However, frequent replacement of chamber components reduces service life of the processing chamber, increases chamber downtime, increases maintenance frequency, and reduces substrate yields.

Therefore, there is a need for an improved method for forming chamber components that are more resistive to a plasma processing chamber environment.

### SUMMARY

Embodiments described herein generally relate to a chamber component for a plasma process chamber and methods for fabricating and using the same.

In one aspect, a chamber component used within a plasma processing chamber is provided. The chamber component includes a metallic base material comprising a surface that has an average peak-to-valley distance (Rz_{AVG}) of less than or equal to about 20 micro inches (0.508 microns). The chamber component also includes a silica coating formed over the surface.

In another aspect, a method of fabricating a chamber component for use in a plasma processing environment is provided. The method includes forming a body of the chamber component from a metal material, wherein the body has a roughened surface. The method also includes machining the roughened surface to render a machined surface that has an average peak-to-valley distance (Rz_{AVG}) of less than or equal to about 20 micro inches (0.508 microns). Further, the method includes depositing a layer of silica on the machined surface of the body. Further, the method includes heating the layer of silica and the metal material.

In yet another aspect, a method is provided. The method includes plasma treating a process chamber with a plasma containing nitrogen or oxygen. The process chamber includes a chamber component that includes a metallic base material comprising a surface that has an average peak-to-valley distance (Rz_{AVG}) of less than or equal to about 20 micro inches (0.508 microns). The chamber component also includes a silica coating formed over the surface. The method further includes placing a substrate into the process chamber, wherein a stack is disposed on the substrate. The method also includes plasma treating the stack disposed on the substrate.

In yet a further aspect, a plasma process chamber is provided. The plasma process chamber includes a chamber component. The chamber component includes a metallic base material comprising a surface that has an average peak-to-valley distance (Rz_{AVG}) of less than or equal to about 20 micro inches (0.508 microns). The chamber component also includes a silica coating formed over the surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1A illustrates a sectional view of one embodiment of a plasma processing chamber component that may be used within a processing chamber.

FIG. 1B is an enlarged view of the plasma processing chamber component of FIG. 1A.

FIG. 1C depicts a surface profile of a surface of the plasma processing chamber component of FIG. 1A.

FIG. 2 schematically illustrates a plasma processing system.

FIG. 3 is a data sheet showing testing of the plasma resistant coating on the chamber component as described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

A chamber component for a plasma process chamber and methods for fabricating and using the same are disclosed herein. In at least one example, a chamber component used within a plasma processing chamber is provided. The chamber component can be a plasma door, an upper liner, or some other component. The chamber component can include a metallic base material, which can include or be formed of aluminum. The metallic base material can include a surface having an average peak-to-valley distance Rz_{AVG} of less than or equal to about 20 micro inches (0.508 microns). In at least one example, the surface can be relatively rough and can be polished or otherwise machined to the noted Rz_{AVG}. A silica coating, or plasma resistant coating, can be formed over the surface and then heat-treated to conform the silica coating to the surface and to smooth out the silica coating. An outer surface of the silica coating can be exposed to plasma during processing of a substrate.

In at least one example, the silica coating can be applied in a semi-liquid state over the Rz_{AVG}, and with the Rz_{AVG} of the surface of the chamber component advantageously being less than or equal to about 20 micro inches, the silica coating can be readily moved over the surface to entirely or substantially cover the surface with the silica coating. The silica coating covered over the surface of the metallic base material can advantageously prevent trace metals from the metallic base material from leaching out and contaminating a substrate undergoing processing, which can increase substrate yields and performance. Coating the surface of the chamber component can also extend the service life of the chamber component, and the processing chamber more generally. Also, the silica coating can protect the metallic base material during cleaning processes.

Words of approximation, such as “about” and “substantially”, may each be used herein in the sense of “at, near, or nearly at,” or “within 5% of a stated value,” or “within acceptable manufacturing tolerances,” or any logical combination thereof, for example.

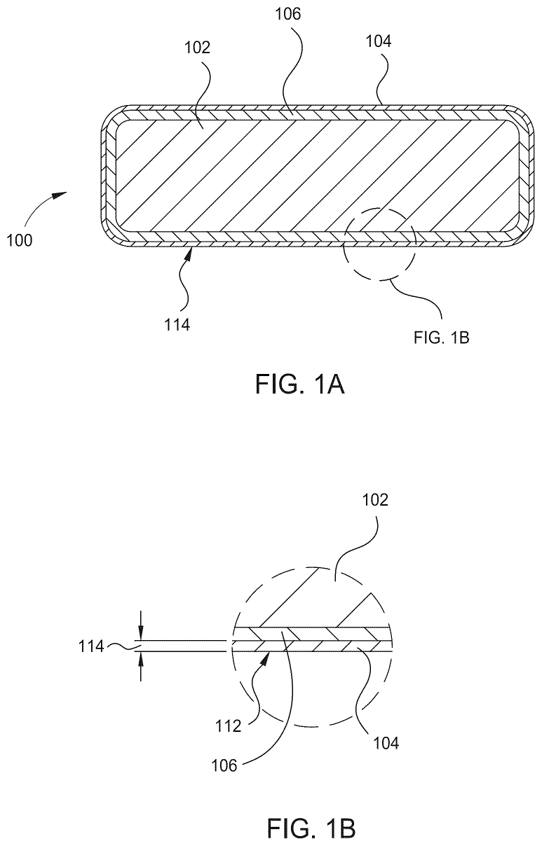

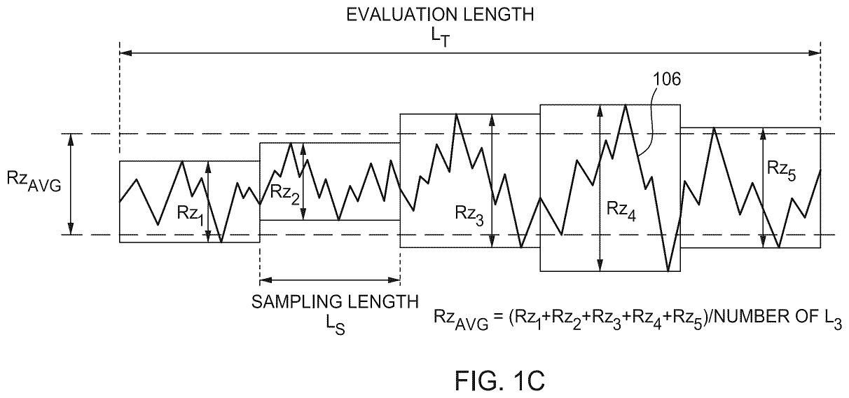

With reference now to FIGS. 1A and 1B, FIG. 1A illustrates a sectional view of one embodiment of a plasma processing chamber component 100 that may be used within a processing chamber. FIG. 1B is an enlarged view of the plasma processing chamber component 100 of FIG. 1A. Although the chamber component 100 is shown in FIG. 1A as having a rectangular cross-section, for the purposes of discussion it is understood that the chamber component 100 may take the form of any chamber part, including, but not limited to, a chamber body, a chamber body upper liner, a chamber body lower liner, chamber body plasma door, a cathode liner, a chamber lid gas ring, a throttling gate valve spool, a plasma screen, a pedestal, a substrate support assembly, a showerhead, a gas nozzle, and the like.

The chamber component 100 has at least one exposed surface 112 that is exposed to the plasma environment within the processing chamber when in use. The chamber component 100 includes a body 102 having a plasma resistant coating 104 disposed on a surface 106 of the body 102. The surface 106 can be an outer surface of the body 102. The plasma resistant coating 104 fills in pits and valleys of the surface 106 (e.g., to “planarize” the surface 106) to create a relatively smooth exposed surface 112. The exposed surface 112 can be substantially planar.

The body 102 of the chamber component 100 can be a metallic material, such as aluminum, stainless steel as well as alloys thereof, or a ceramic material. The plasma resistant coating 104 can be a silica material (e.g., silicon dioxide (SiO₂)), which can be fully crystallized. In one or more embodiments, the plasma resistant coating 104 can be deposited as a crystal. In one or more other embodiments, the plasma resistant coating 104 can be treated post-deposition to crystalline the material. In one or more embodiments, a thickness 114 of the plasma resistant coating 104 can be about 0.2 microns (μm) to about 10 μm, or greater. In one or more embodiments, a thickness 114 of the plasma resistant coating 104 can be about 2 microns (μm) to about 8 μm. In one or more embodiments, a thickness 114 of the plasma resistant coating 104 can be about 4 microns (μm) to about 6 μm. In one or more embodiments, the plasma resistant coating 104 can have a porosity of less than about 1% by volume, such as less than 0.5% by volume, such as less than 0.25% by volume. In one or more embodiments, the surface 106 can be finished to an average surface roughness (Ra) of about 4 micro-inches (μ″) to about 80 μ″ (or about 0.1016 μm to about 2.032 μm). In such embodiments, the plasma resistant coating 104 can have an Ra less than the Ra of the surface 106. In one or more further embodiments, the surface 106 can be finished to an average surface roughness (Ra) of about 4 μ″ to about 50 μ″ (or about 0.1016 μm to about 1.27 μm). In one or more further embodiments, the surface 106 can be finished to an average surface roughness (Ra) of about 4 μ″ to about 25 μ″ (or about 0.1016 μm to about 0.635 μm). In one or more embodiments, the surface 106 can be finished to an average surface roughness (Ra) of about 4 μ″ to about 15 μ″ (or about 0.1016 μm to about 0.381 μm).

The plasma resistant coating 104 can be applied using techniques such as painting, spreading, or spraying the surface 106 with a silica material. Then, the plasma resistant coating 104 can be annealed by placing the coated chamber component 100 in a furnace. The heating relieves surface tension in the plasma resistant coating 104, which makes the plasma resistant coating 104 conformal or flat as well as smooth. The heating may be at a temperature of about 200 degrees Celsius, or less. The heating may be performed for a predetermined time, such as about one hour.

In one or more embodiments, prior to applying the plasma resistant coating 104 to the surface 106, which can be roughened, the surface 106 can be polished or otherwise machined so that the surface 106 has an average peak-to-valley distance Rz_{AVG} less than or equal to a predetermined value. In one or more embodiments, the surface 106 can advantageously have an Rz_{AVG} of less than or equal to about 20 μ″ (or about 0.508 μm). In this way, when the plasma resistant coating 104 is applied to the surface 106, the plasma resistant coating 104 can spread over and cover or substantially cover the surface 106, such as by at least ninety percent (90%) of the area of the surface 106, such as by at least ninety-five percent (95%) of the area of the surface 106, such as by at least ninety-nine percent (99%) of the area of the surface 106. The Rz_{AVG} of less than or equal to about 20 μ″ (or about 0.508 μm) of the surface 106 can facilitate the spreading and coverage of the plasma resistant coating 104, especially where the plasma resistant coating 104 is in a liquid or semi-liquid state during application.

In some embodiments, the surface 106 can have an Rz_{AVG} of less than or equal to about 20 μ″ (or about 0.508 μm) and greater than about 10 μ″ (or about 0.254 μm). Generally, a lower Rz_{AVG} corresponds to a less rough surface while a higher Rz_{AVG} corresponds to a rougher surface. In one or more embodiments, the surface 106 can have an Rz_{AVG} of less than or equal to about 17 μ″ (or about 0.4318 μm).In one or more embodiments, the surface 106 can have an Rz_{AVG} of less than or equal to about 15 μ″ (or about 0.381 μm). In one or more embodiments, the surface 106 can have an Rz_{AVG} of less than or equal to about 12 μ″ (or about 0.3048 μm).In one or more embodiments, the surface 106 can have an Rz_{AVG} of less than or equal to about 20 μ″ (or about 0.381 μm) and greater than about 5 μ″ (or about 0.127 μm).

FIG. 1C depicts a roughness profile of the surface 106 according to one or more embodiments of the present disclosure. The average peak-to-valley distance Rz_{AVG} of the surface 106 can be determined according to the example manner described below.

As shown in FIG. 1C, the surface 106 can have an evaluation length L_{T}, which can be an entire length of the surface 106 or a predetermined portion thereof. In one or more embodiments, the evaluation length L_{T} can be at least one inch. The evaluation length L_{T} can be divided into equal lengths, or sampling lengths L_{S}. In FIG. 1C, the evaluation length L_{T} has been divided into five (5) equal sampling lengths. The evaluation length L_{T} can be divided into more or less than five (5) sampling lengths in other embodiments.

A peak-to-valley distance of the surface 106 can be measured for each of the sampling lengths L_{S}. For instance, a first peak-to-valley distance Rz₁ can be determined for a first sampling length, a second peak-to-valley distance Rz₂ can be determined for a second sampling length, a third peak-to-valley distance Rz₃ can be determined for a third sampling length, a fourth peak-to-valley distance Rz₄ can be determined for a fourth sampling length, and a fifth peak-to-valley distance Rz₅ can be determined for a fifth sampling length. These peak-to-valley distances represent the distance from the highest peak to the lowest valley of the surface 106 in their respective sampling lengths L_{S}. These individual peak-to-valley distances can also be referred to as total roughness values for their respective sampling lengths L_{S}.

The average peak-to-valley distance Rz_{AVG} of the surface 106 can be determined by dividing the sum of the peak-to-valley distances determined for each of the sampling lengths by the number of sampling lengths. In this example, the first, second, third, fourth, and fifth peak-to-valley distances Rz₁, Rz₂, Rz₃, Rz₄, and Rz₅ can be added together to determine a sum, and this sum can be divided by five (5), which is the number of sampling lengths in the example of FIG. 1C. As noted above, in one or more embodiments, the surface 106 can advantageously have an Rz_{AVG} of less than or equal to about 20 μ″ (or about 0.508 μm), which can facilitate enhanced coating coverage and performance. In one or more embodiments, the silica coating applied to the surface 106 can have a thickness between about 0.2 microns and about 10 microns, have less than 1% porosity by volume, and can contain less than 2E¹² atoms/centimeters² of aluminum.

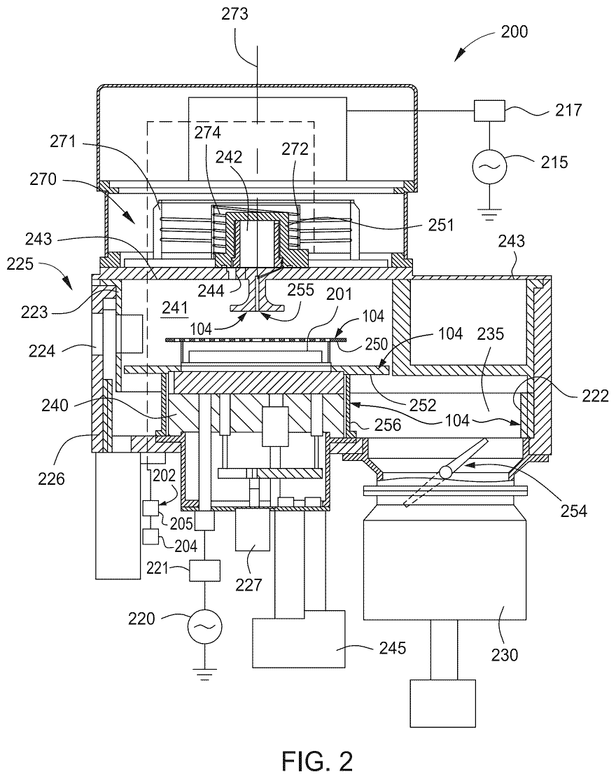

FIG. 2 schematically illustrates a plasma processing system 200. The plasma processing system 200 can include a chamber body 225 defining a processing volume 241. The chamber body 225 includes a sealable slit valve tunnel, or chamber body plasma door 224, to allow entry and egress of a substrate 201 from the processing volume 241. The chamber body 225 includes sidewalls 226 and a lid 243. The sidewalls 226 and lid 243 may be fabricated from metals or ceramic materials and can include the plasma resistant coating 104 as described herein. The plasma processing system 200 further includes an antenna assembly 270 disposed over the lid 243 of the chamber body 225. A radio frequency (RF) power source 215 and a matching network 217 are coupled to the antenna assembly 270 to provide energy for plasma generation.

The antenna assembly 270 can include one or more coil antennas disposed coaxial with an axis of symmetry 273 (e.g., a longitudinal axis) of the plasma processing system 200. As shown in FIG. 2, the antenna assembly 270 includes an outer coil antenna 271 and an inner coil antenna 272 disposed over the lid 243. In one or more embodiments, the coil antennas 271, 272 may be independently controlled. It should be noted that even though two coaxial antennas are included in the plasma processing system 200, other configurations are contemplated, such as configurations having one coil antenna, three or more coil antennas, etc.

The inner coil antenna 272 includes one or more electrical conductors wound as a spiral with small pitch and forming an inner antenna volume 274. A magnetic field establishes an inner antenna volume 274 of the inner coil antenna 272 when an electrical current goes through the one or more electrical conductors. As discussed below, embodiments of the present disclosure provide a chamber extension volume within the inner antenna volume 274 of the inner coil antenna 272 to generate plasma using the magnetic field in the inner antenna volume 274.

It should be noted, that the inner coil antenna 272 and the outer coil antenna 271 may have other shapes, for example to match a certain shape of a chamber wall, or to achieve symmetry or asymmetry within the chamber body 225. In one or more embodiments, the inner coil antenna 272 and the outer coil antenna 271 may form inner antenna volumes in the shape of hyper-rectangle.

The plasma processing system 200 further includes a substrate support 240 disposed, at least in part, in the processing volume 241. The substrate support 240 supports the substrate 201 during processing. In one or more embodiments, the substrate support 240 is an electrostatic chuck. A bias power source 220 and a matching network 221 may be connected to the substrate support 240. The bias power source 220 provides bias potential to a plasma generated in the processing volume 241.

In the embodiment shown in FIG. 2, the substrate support 240 is surrounded by a ring-shaped cathode liner 256. A plasma containment screen or baffle 252 covers the top of the cathode liner 256 and covers a peripheral portion of the substrate support 240. The substrate support 240 may contain materials that are incompatible or vulnerable to a corrosive plasma processing environment, and the cathode liner 256 and the baffle 252 isolate the substrate support 240 from the plasma and contain the plasma within the processing volume 241, respectively. In one or more embodiments, the cathode liner 256 and baffles 252 may include a high purity plasma resistant coating 104 that is resistive to the plasma contained within the processing volume 241. The plasma resistant coating 104 on the cathode liner 256 and baffles 252 can improve the service life of the cathode liner 256 and baffles 252.

A plasma screen 250 is disposed on top of the substrate support 240 to control the spatial distribution of charged and neutral species of the plasma across the surface of the substrate 201. In one or more embodiments, the plasma screen 250 includes a substantially flat member electrically isolated from the chamber walls and comprises a plurality of apertures that vertically extend through the flat member. The plasma screen 250 may include a high purity plasma resistant coating 104 as described above which resists the process environment within the processing volume 241.

The lid 243 has an opening 244 to allow entrance of one or more processing gases. In one or more embodiments, the opening 244 may be disposed near a center axis of the plasma processing system 200 that corresponds to the center of the substrate 201 being processed.

The plasma processing system 200 includes a chamber extension 251 disposed over the lid 243 covering the opening 244. In one or more embodiments, the chamber extension 251 is disposed inside a coil antenna of the antenna assembly 270. The chamber extension 251 defines an extension volume 242 in fluid communication with the processing volume 241 via the opening 244.

The plasma processing system 200 further includes a gas distribution showerhead shown as a baffle nozzle assembly 255 disposed adjacent to the opening 244 in the processing volume 241 and the extension volume 242. The baffle nozzle assembly 255 directs one or more processing gases into the processing volume 241 through the extension volume 242. In one or more embodiments, the baffle nozzle assembly 255 has a by-pass path allowing a processing gas to enter the processing volume 241 without going through the extension volume 242. The baffle nozzle assembly 255 may be fabricated from aluminum and can be coated with the plasma resistant coating 104.

Because the extension volume 242 is within the inner antenna volume 274, processing gas in the extension volume 242 is exposed to the magnetic field of the inner coil antenna 272 prior to entering the processing volume 241. The usage of the extension volume 242 increases the plasma intensity within the processing volume 241 without an increase in power applied to the inner coil antenna 272 or the outer coil antenna 271.

The plasma processing system 200 also includes a pump 230, and a throttle valve 235 to provide vacuum and exhaust for the processing volume 241. The throttle valve 235 may include a gate valve spool 254. The gate valve spool 254 may be fabricated from aluminum. The plasma processing system 200 further includes a chiller 245 to control the temperature of the plasma processing system 200. The throttle valve 235 may be disposed between the pump 230 and the chamber body 225 and may be operable to control pressure within the chamber body 225.

The plasma processing system 200 also includes a gas delivery system 202 to provide one or more processing gases to the processing volume 241. The gas delivery system 202 is located in a housing 205 disposed directly adjacent to, such as under, the chamber body 225. The gas delivery system 202 selectively couples one or more gas sources located in one or more gas panels 204 to the baffle nozzle assembly 255 to provide process gases to the chamber body 225. The gas delivery system 202 is connected to the baffle nozzle assembly 255 to provide gases to the processing volume 241. The housing 205 is located in close proximity to the chamber body 225 to reduce gas transition time when changing gases, minimize gas usage, and minimize gas waste.

The plasma processing system 200 further includes a lift system 227 for raising and lowering the substrate support 240 that supports the substrate 201 in the chamber body 225.

In the embodiment shown, the chamber body 225 is protected by a lower liner 222 and an upper liner 223 which may be aluminum and can include the plasma resistant coating 104.

The gas delivery system 202 may be used to supply at least two different gas mixtures to the chamber body 225 at an instantaneous rate as further described below. In an optional embodiment, the plasma processing system 200 may include a spectral monitor operable to measure the depth of an etched trench and a deposited film thickness as the trench is being formed in the chamber body 225, with the ability to use other spectral features to determine the state of the reactor. The plasma processing system 200 may accommodate a variety of substrate sizes, for example a substrate diameter of up to about 300 mm or greater.

Various chamber components in the processing system 200 described above may be fabricated using the plasma resistant coating 104 as described above. These chamber components are frequently exposed to the plasma processing environment. For example, the plasma resistant coating 104 may be applied to the chamber body 225, the chamber body upper liner 223, the chamber body lower liner 222, the chamber body plasma door 224, a cathode liner 256, a chamber lid gas ring, a throttling gate valve spool 254, a plasma screen 250, the baffle nozzle assembly 255, baffles 252, and a pedestal or substrate support 240.

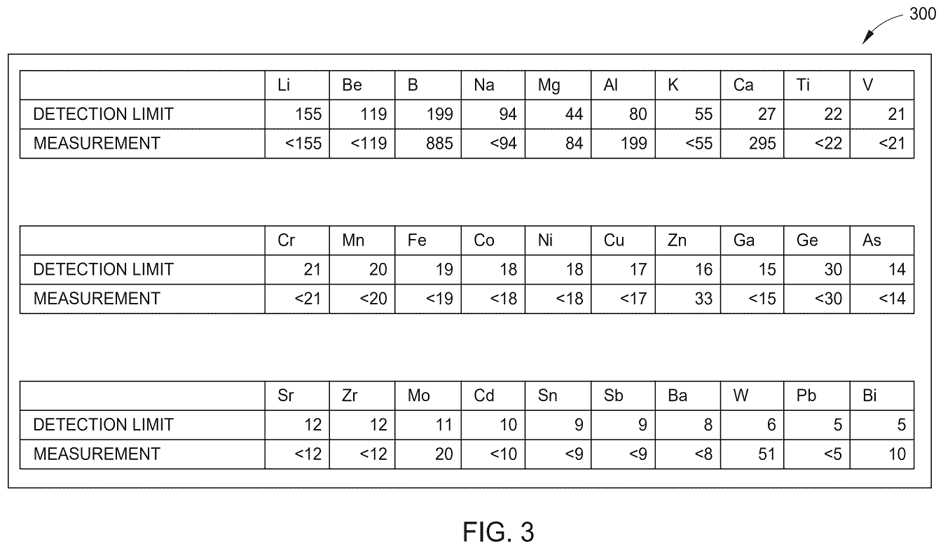

FIG. 3 is a data sheet 300 showing testing of the plasma resistant coating 104 on the chamber component 100. The testing of the plasma resistant coating 104 showed low levels of trace metals in or on the plasma resistant coating 104. This evidences that the plasma resistant coating 104 effectively blocks metal atoms from the body 102 of the chamber component 100 from leaching into the coating 104. For example, aluminum concentration in the plasma resistant coating 104 was less than about 2E¹² atoms/centimeter squared (atoms/cm²). Many other trace metals were present in or on the plasma resistant coating 104 but were below critical levels.

The disclosed process chamber and components thereof may be used in one or more substrate processing operations. The below description provides one such exemplary process, but other processes are contemplated.

With reference again to FIG. 2, in one or more examples, a process chamber, such as the chamber body 225 thereof, is treated with a H₂ plasma without a substrate placed therein. The plasma treatment of the chamber body 225 prior to introducing a substrate to the chamber may be referred to as Plasma Every Wafer (PEW). The plasma treating of the process chamber, or PEW, may include introducing one or more gases, such as O₂, N₂, NH₃, Ar, H₂, He, or combinations thereof, into the chamber body 225, and energizing the one or more gases to form a plasma. Alternatively, PEW may include introducing a plasma containing radicals and/or ions of oxygen, nitrogen, hydrogen, ammonia, hydroxide or combination thereof into the chamber body 225, and the plasma is formed in a remote plasma source outside of the chamber body 225.

In one or more embodiments, NH₃ and Ar gases are introduced into the chamber body 225. In another embodiment, O₂ and H₂ gases are introduced into the chamber body 225. In another embodiment, O₂ and Ar gases are introduced into the chamber body 225. In another embodiment, O₂ gas is introduced into the chamber body 225. In yet another embodiment, N₂ gas is introduced into the chamber body 225. Typically the plasma treatment of the chamber body 225 prior to introducing the substrate involves introducing or forming a plasma containing oxygen or nitrogen in the process chamber.

In some embodiments, the one or more gases are energized by an RF power source. The RF power may be pulsed at 2% to 70% duty cycle and may range from about 100 W to about 2500 W. The RF power may be a continuous wave ranging from about 100 W to about 2500 W. The chamber body 225 may have a chamber pressure ranging from about 10 milli Torr (mT) to about 200 mT during the plasma treatment of the chamber body 225. The process temperature, which may be the temperature of the substrate support pedestal, such as the substrate support 240, may range from 20 degrees C to about 500 degrees C.

Thereafter, a substrate, optionally having a gate stack disposed thereon, is treated by a hydrogen containing plasma within the chamber body 225. The hydrogen-containing plasma treatment of the substrate may include introducing a hydrogen containing gas, such as H₂ gas, or a hydrogen containing gas and an inert gas, such as Ar gas, into the chamber body 225, and energizing the H₂ gas or H₂/Ar gases to form a hydrogen containing plasma. Ar gas may be added to the H₂ gas in order to improve the service lifetime of the chamber body 225 (further mitigating the hydrogen containing plasma attack of components inside the chamber body 225) and to modulate the H* radical concentrations. In some embodiments, the H₂ gas or H₂/Ar gases are energized by an RF power source, such as the RF power source 215. The RF power may be pulsed at 2% to 60% duty cycle and may range from about 100 W to about 2500 W. The RF power may be a continuous wave ranging from about 100 W to about 2500 W. The chamber body 225 may have a chamber pressure ranging from about 10 mT to about 200 mT during the hydrogen containing plasma treatment of the substrate. The process temperature, which may be the temperature of the substrate support, may range from 20° C. to about 500° C. The substrate may be treated by the hydrogen containing plasma for about 10 to 360 seconds. In one or more embodiments, the chamber pressure is about 100 mT, the H₂ gas is flowed into the chamber body 225 at about 25 standard cubic centimeters per minute (sccm) and Ar gas is flowed into the chamber body 225 at about 975 sccm, the RF power is about 500 W, the process temperature is about 400 degrees C, and the substrate is treated by the hydrogen containing plasma for about 30 to 90 seconds. After the substrate is treated with the hydrogen containing plasma, the substrate may be removed from the chamber body 225.

In one or more embodiments, a substrate having a gate stack disposed thereon can be treated by a plasma containing ammonia within the chamber body 225. In at least one embodiment, the plasma containing ammonia can be formed by introducing a hydrogen containing gas and an inert gas into the process chamber and energizing the hydrogen containing gas and the inert gas. In one or more other embodiments, plasma treating the substrate having the stack disposed thereon can include treating the substrate and stack with a plasma containing nitrogen. In one or more further embodiments, the substrate having the stack disposed thereon can be treated with a N₂, O₂, He, or NH₃ plasma. In at least one example, the gate stack can include one or more conductive layers and one or more insulating layers, e.g., forming a gate structure for a field effect transistor (FET), such as a metal oxide semiconductor FET (MOSFET).

It is contemplated that other and further processes may be performed within the chamber body 225. Moreover, it is contemplated that coated chamber components may be utilized with other and additional processes.

With the example and explanations above, the features and spirits of the embodiments of the disclosure are described. Those skilled in the art will readily observe that numerous modifications and alterations may be made. Accordingly, the above disclosure should be construed as limited only by the metes and bounds of the appended claims.

1. A chamber component used within a plasma processing chamber, comprising:
a metallic base material comprising a surface, wherein the surface has an average peak-to-valley distance (Rz_{AVG}) of less than or equal to about 20 micro inches (0.508 microns); and
a silica coating formed over the surface.

2. The chamber component of claim 1, wherein the silica coating has a thickness between about 0.2 microns and about 10 microns.

3. The chamber component of claim 1, wherein the silica coating has less than 1% porosity by volume.

4. The chamber component of claim 1, wherein the silica coating contains less than 2E¹² atoms/centimeters² of aluminum.

5. The chamber component of claim 1, wherein the metallic base material comprises aluminum.

6. The chamber component of claim 1, wherein the chamber component is a chamber body plasma door.

7. The chamber component of claim 1, wherein the chamber component is a chamber body upper liner.

8. The chamber component of claim 1, wherein the chamber component comprises at least one of: a gas distribution showerhead, a nozzle assembly, or a baffle.

9. The chamber component of claim 1, wherein the chamber component comprises a liner.

10. The chamber component of claim 1, wherein the surface has an average surface roughness (Ra) of between 4 micro-inches and 80 micro-inches and the silica coating has a surface that has an Ra that is less than the Ra of the surface.

11. A method for fabricating a chamber component for use in a plasma processing environment, comprising:
forming a body of the chamber component from a metal material, wherein the body has a roughened surface;
machining the roughened surface to render a machined surface that has an average peak-to-valley distance (Rz_{AVG}) of less than or equal to about 20 micro inches (0.508 microns);
depositing a layer of silica on the machined surface; and
heating the layer of silica and the metal material.

12. The method of claim 11, wherein the layer of silica has a thickness between about 0.2 microns and about 10 microns, has less than 1% porosity by volume, and contains less than 2E¹² atoms/centimeters² of aluminum.

13. The method of claim 11, wherein the metal material comprises aluminum.

14. The method of claim 11, wherein the chamber component is a chamber body plasma door.

15. The method of claim 11, wherein the chamber component is a chamber body upper liner.

16. A method, comprising:
plasma treating a process chamber with a plasma containing nitrogen or oxygen, the process chamber including a chamber component comprising:
a metallic base material comprising a surface that has an average peak-to-valley distance (Rz_{AVG}) of less than or equal to about 20 micro inches (0.508 microns); and
a silica coating formed over the surface;
placing a substrate into the process chamber, wherein a stack is disposed on the substrate; and
plasma treating the stack disposed on the substrate.

17. The method of claim 16, wherein the plasma containing nitrogen or oxygen is formed by introducing one or more gases into the process chamber and energizing the one or more gases.

18. The method of claim 16, wherein the plasma treating the stack comprises treating the stack with a plasma containing ammonia.

19. The method of claim 18, wherein forming the plasma containing ammonia further comprises introducing a hydrogen containing gas and an inert gas into the process chamber and energizing the hydrogen containing gas and the inert gas.

20. The method of claim 16, wherein the plasma treating the stack comprises treating the stack with a plasma containing nitrogen.
